(19) United States
(12) Patent Application Publication
(10) Pub. No.: US 2024/0313023 A1
(43) Pub. Date: Sep. 19, 2024

(54) IMAGE SENSING DEVICE

(71) Applicant: SK hynix Inc., Icheon-si (KR)

(72) Inventor: Jae Hyung JANG, Icheon-si (KR)

(21) Appl. No.: 18/398,028

(22) Filed: Dec. 27, 2023

(30) Foreign Application Priority Data
Mar. 15, 2023 (KR) 10-2023-0034102

(51) Int. Cl. H01L 27/146

(52) U.S. Cl. CPC H01L 27/14634; H01L 27/14627; H01L 27/14645; H01L 27/1465; H01L 27/14652

(57) ABSTRACT

An image sensing device includes a first substrate and a second substrate. The first substrate includes a first infrared photoelectric conversion element structured to respond to infrared light to generate photocharges corresponding to an intensity of infrared light received by the first infrared photoelectric conversion element, and a color photoelectric conversion element structured to respond to visible light to generate photocharges corresponding to an intensity of visible light received by the color photoelectric conversion element. The second substrate stacked on the first substrate and configured to include a second infrared photoelectric conversion element structured to respond to infrared light to generate photocharges corresponding to an intensity of infrared light that passes through the first infrared photoelectric conversion element and is received by the second infrared photoelectric conversion element.

### CROSS-REFERENCE TO RELATED APPLICATION

This patent document claims the priority and benefits of Korean patent application No. 10-2023-0034102, filed on Mar. 15, 2023, the disclosure of which is incorporated herein by reference in its entirety as part of the disclosure of this patent document.

### TECHNICAL FIELD

The technology and implementations disclosed in this patent document generally relate to an image sensing device capable of acquiring an image of a target object.

### BACKGROUND

An image sensor is a device for capturing at least one image using semiconductor characteristics that react to light incident thereon to produce an image. With the increasing development of computer industries and communication industries, the demand for high-quality and high-performance image sensing devices in, for example, smartphones, digital cameras, game consoles, Internet of Things (IoT), robots, surveillance cameras, medical micro-cameras, etc., has been rapidly increasing.

Image sensors may be broadly classified into CCD (Charge Coupled Device) image sensors and CMOS (Complementary Metal Oxide Semiconductor) image sensors. The CCD image sensors may be superior to the CMOS image sensor in terms of noise and image quality. However, the CMOS image sensor may have a simpler and more convenient driving schemes, and thus may be preferred in some applications.

In addition, the CMOS image sensor may integrate a signal processing circuit in a single chip, making it easy to miniaturize the sensors for implementation in a product, with the added benefit of consuming lower power consumption. The CMOS image sensors can be fabricated using a CMOS fabrication technology, which results in low manufacturing cost. The CMOS image sensors have been widely used due to their suitability for implementation in mobile devices.

There have been much developments and studies for measuring range and depth (i.e., a distance to a target object) using image sensors. For example, demand for the above-mentioned depth measurement schemes using image sensors is rapidly increasing in various devices, for example, security devices, medical devices, automobiles, game consoles, virtual reality (VR)/augmented reality (AR) devices, mobile devices, etc. Methods for measuring depth information using one or more image sensors are mainly classified into a triangulation method, a Time of Flight (TOF) method, and an interferometry method. Among above-mentioned depth measurement methods, the Time of Flight (TOF) method becomes popular because of its wide range of utilization, high processing speed, and cost advantages. The TOF method measures a distance using emitted light and reflected light.

The TOF method may be mainly classified into two different types, i.e., a direct method and an indirect method, depending on whether it is a round-trip time or the phase difference that determines the distance. Although the principles in which the distance (i.e., depth) to a target object is calculated using emitted light and reflected light are commonly applied to the direct method and the indirect method, the direct method and the indirect method may have different measurement methods.

The image sensor may be a three-dimensional (3D) image sensor capable of acquiring a color image as well as a depth image. In this case, the image sensor may include a pixel for acquiring a depth image together with a pixel for acquiring a color image.

### SUMMARY

Various embodiments of the disclosed technology relate to an image sensing device in which heterogeneous pixels are efficiently arranged.

In accordance with an embodiment of the disclosed technology, an image sensing device may include a first substrate configured to include a first infrared photoelectric conversion element structured to respond to infrared light to generate photocharges corresponding to an intensity of infrared light received by the first infrared photoelectric conversion element, and a color photoelectric conversion element structured to respond to visible light to generate photocharges corresponding to an intensity of visible light received by the color photoelectric conversion element; and a second substrate stacked on the first substrate and configured to include a second infrared photoelectric conversion element structured to respond to infrared light to generate photocharges corresponding to an intensity of infrared light that passes through the first infrared photoelectric conversion element and is received by the second infrared photoelectric conversion element.

In accordance with another embodiment of the disclosed technology, an image sensing device may include a pixel array configured to include an infrared pixel for generating photocharges corresponding to intensity of infrared light and a color pixel for generating photocharges corresponding to intensity of visible light. The infrared pixel may include photoelectric conversion elements disposed in each of a first substrate and a second substrate that are stacked on each other, and the color pixel may include a photoelectric conversion element disposed in the first substrate.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a pixel array shown in FIG. 1 based on some implementations of the disclosed technology.

FIG. 3 is a schematic diagram briefly illustrating an example of an arrangement shape of elements on a first substrate constituting the pixel array shown in FIG. 2 based on some implementations of the disclosed technology.

FIG. 4 is a schematic diagram briefly illustrating one example of an arrangement shape of elements on a second substrate constituting the pixel array shown in FIG. 2 based on some implementations of the disclosed technology.

FIG. 5 is a schematic diagram briefly illustrating another example of an arrangement shape of elements on a second substrate constituting the pixel array shown in FIG. 2 based on some implementations of the disclosed technology.

FIG. 6 is a cross-sectional view illustrating an example of the pixel array taken along the line A-A′ shown in FIG. 2 based on some implementations of the disclosed technology.

FIG. 7 is a cross-sectional view illustrating another example of the pixel array taken along the line A-A′ shown in FIG. 2 based on some implementations of the disclosed technology.

FIG. 8 is a cross-sectional view illustrating another example of the pixel array taken along the line A-A′ shown in FIG. 2 based on some implementations of the disclosed technology.

FIG. 9 is a cross-sectional view illustrating another example of the pixel array taken along the line A-A′ shown in FIG. 2 based on some implementations of the disclosed technology.

FIG. 10 is a cross-sectional view illustrating another example of the pixel array taken along the line A-A′ shown in FIG. 2 based on some implementations of the disclosed technology.

FIG. 11 is a cross-sectional view illustrating another example of the pixel array taken along the line A-A′ shown in FIG. 2 based on some implementations of the disclosed technology.

FIG. 12 is a cross-sectional view illustrating another example of the pixel array taken along the line A-A′ shown in FIG. 2 based on some implementations of the disclosed technology.

FIG. 13 is a cross-sectional view illustrating another example of the pixel array taken along the line A-A′ shown in FIG. 2 based on some implementations of the disclosed technology.

### DETAILED DESCRIPTION

This patent document provides implementations and examples of an image sensing device capable of acquiring an image of a target object that may be used in configurations to substantially address one or more technical or engineering issues and to mitigate limitations or disadvantages encountered in some other image sensing devices. Some implementations of the disclosed technology relate to an image sensing device in which heterogeneous pixels are efficiently arranged. The disclosed technology provides various implementations of an image sensing device which can enable photoelectric conversion elements to be arranged at optimal positions in a structure in which color pixels and depth pixels are mixed and arranged, thereby improving pixel performance and maximizing area efficiency.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

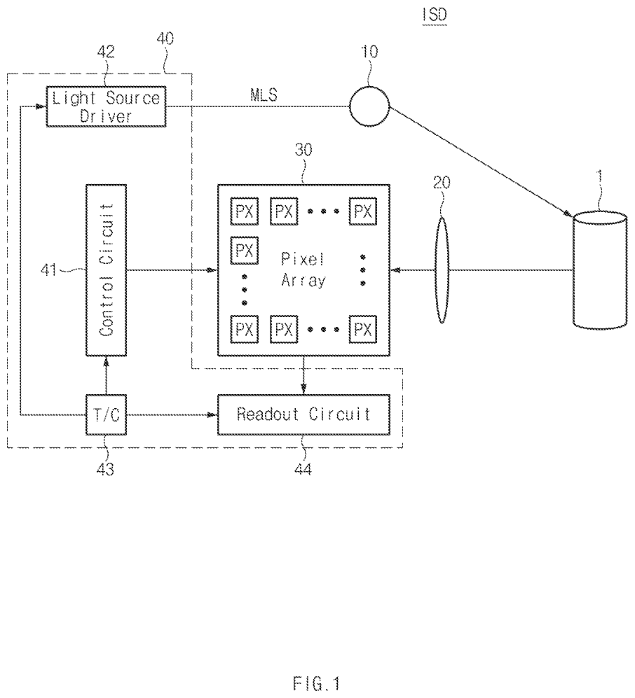

FIG. 1 is a block diagram illustrating an example of an image sensing device ISD based on some implementations of the disclosed technology.

Referring to FIG. 1, the image sensing device ISD may acquire a color image of a target object 1 and a depth image indicating a distance to the target object 1. In some implementations, the image sensing device ISD may measure the distance to the target object 1 using the Time of Flight (TOF) principle.

The image sensing device ISD may include a light source 10, a lens module 20, a pixel array 30, and a control block or circuit module 40.

The pixel array 30 include pixels (PXs) for detecting light incident to the pixel array 30 and includes two types of pixels for performing different sensing operations: a first type designated pixels that detect light from a target object or scene to capture the image of the target object or scene and a second type designated pixels to detect modulated light that is generated by the light source 10 to illuminate the target object or scene and is reflected towards the pixel array 30. The output signal from each second type designated pixel can be processed to extract information on a distance between the target object or scene and the second type designated pixel in the pixel array 30. This design of the pixel array 30 allows capturing of both the image of the target object or scene and the depth information of the target object or scene.

The light source 10 may emit light to a target object 1 upon receiving a modulated light signal (MLS) from a light source driver 42 within the control block or circuit module 40. The light source 10 may be a laser diode (LD) or a light emitting diode (LED) for emitting light (e.g., near infrared (NIR) light, infrared (IR) light or visible light) having a specific wavelength band, or may be any one of a Near Infrared Laser (NIR), a point light source, a monochromatic light source combined with a white lamp or a monochromator, and a combination of other laser sources. For example, the light source 10 may emit infrared light having a wavelength of 800 nm to 1000 nm. Light emitted from the light source 10 may be light (i.e., modulated light) modulated by a predetermined frequency. Although FIG. 1 shows only one light source 10 as an example, other implementations are also possible. For example, a plurality of light sources 10 may also be implemented to illuminate the target object 1 and are arranged in the vicinity of the lens module 20 to allow the lens module 20 to collect the reflected or scattered light from the target object 1 under illumination of light from the plurality of light sources 10 and to direct such collected light to the pixel array 30. The modulated light emitted from the light source 10 is detected by the second type designated pixels distributed in the pixel array 30 to extract information on the distances between the target object 1 and the designated pixels in the pixel array 30.

The lens module 20 may collect light reflected from the target object 1, and allow the collected light to be focused onto pixels (PXs) of the pixel array 30. For example, the lens module 20 may include a focusing lens having a surface formed of or including glass or plastic or another cylindrical optical element having a surface formed of or including glass or plastic. The lens module 20 may include a plurality of lenses that is arranged to be focused upon an optical axis.

The pixel array 30 may include unit pixels (PXs) consecutively arranged in a two-dimensional (2D) matrix structure in which unit pixels are arranged in a column direction and a row direction perpendicular to the column direction. The unit pixels (PXs) may be formed over at least one semiconductor substrate. Each unit pixel (PX) may convert incident light received through the lens module 20 into an electrical signal corresponding to the amount of incident light, and thus output a pixel signal, which is the electrical signal. In this case, the pixel signal may include a signal indicating the color of the target object 1 and/or a signal indicating the distance to the target object 1.

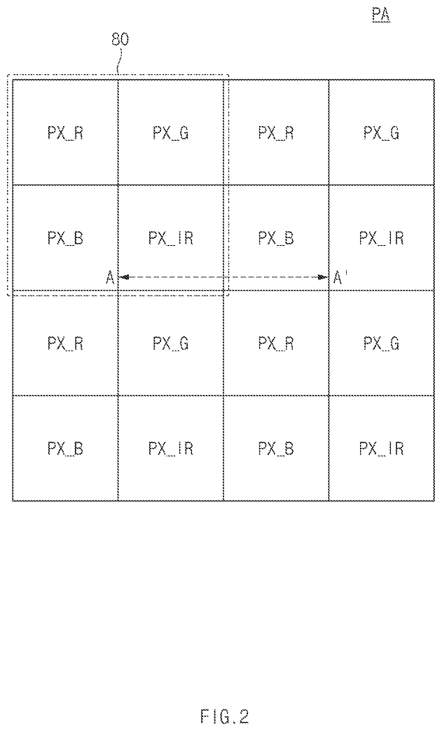

Each unit pixel (PX) in the pixel array 30 in FIG. 1 may be or include a first type pixel for image sensing such as a color pixel for generating a pixel signal by selectively sensing light of a specific wavelength band (or color) of visible light incident from a scene, or may be or correspond to a second type designated pixel such as an infrared pixel for generating a pixel signal by detecting reflected light generated when modulated light emitted from the light source 10 is reflected from the target object 1 and incident upon the target object 1 to provide the depth information at the pixel. Although the embodiment of the disclosed technology has disclosed that an infrared pixel is a depth pixel for calculating the distance to the target object 1, other implementations are also possible. For example, the infrared pixel may be a pixel for generating an infrared light image by simply sensing infrared light incident from a scene rather than the reflected light, similar to how the color pixel detects the color image. A more detailed structure and operations of each unit pixel (PX) will hereinafter be described with reference to the drawings from FIG. 2.

The control block 40 may use its light source driver 42 to control the light source 10 to emit light to the target object 1 and process each pixel signal corresponding to light reflected from the target object 1 by driving unit pixels (PXs) of the pixel array 30. The control block 40 may thus process the output signal from each designated pixel for depth sensing to measure the distance to the surface of the target object 1 using the processed result or may acquire a color image corresponding to the scene by other pixels in the pixel array 30.

As shown in the example in FIG. 1, the control block 40 may include a control circuit 41 for controlling and operating the pixels in the pixel array 30, the light source driver 42 for controlling the light source 10 to produce the modulated light, a readout circuit 44 for reading out signals from pixels in the pixel array 30, and a timing controller 43 for controlling the timing operations of the control circuit 41 and the readout circuit 44.

The control circuit 41 may drive unit pixels (PXs) of the pixel array 30 in response to a timing signal generated from the timing controller 43. For example, the control circuit 41 may generate a control signal capable of selecting and controlling at least one row line among the plurality of row lines. The control signal may include a transfer signal for transferring photocharges accumulated in a photoelectric conversion element to a floating diffusion (FD) node, a pixel reset signal for controlling a reset transistor, a row selection signal for controlling a selection transistor, or others.

The control circuit 41 may receive a signal from the timing controller 43, and may transmit driving signals including a row selection signal, a pixel reset signal, and a transmission signal to the pixel array 30. A unit pixel included in the pixel array 30 may be activated to perform the operations corresponding to the driving signals.

In some implementations, the control circuit 41 may generate a row selection signal to select one or more rows among the plurality of rows, and may sequentially enable the pixel reset signal and the transmission signal for the unit pixels corresponding to the at least one selected row. Thus, a reference signal and an image signal, which are analog signals generated from each of the imaging pixels of the selected row, may be output from each pixel of the selected row.

The light source driver 42 may generate a modulated light signal MLS capable of driving the light source 10 in response to a control signal from the timing controller 43. The modulated light signal MLS may be a signal that is modulated by a predetermined frequency.

The timing controller 43 may generate a timing signal to control the control circuit 41, the light source driver 42, and the readout circuit 44.

The readout circuit 44 may process pixel signals received from the pixel array 30 under control of the timing controller 43, and may thus generate pixel data formed in a digital signal shape. In some implementations, the readout circuit 44 may include a correlated double sampler (CDS) circuit for performing correlated double sampling on the pixel signals generated from the pixel array 30.

In some implementations, the correlated double sampler (CDS) circuit may sequentially receive a reference signal indicating an electrical signal that is provided to the CDS circuit when a sensing node (e.g., a floating diffusion node) is reset, and an image signal indicating an electrical signal that is provided to the CDS circuit when photocharges generated by the unit pixels are accumulated in the sensing node.

In some implementations, the reference signal indicating unique reset noise of each pixel and the image signal indicating the intensity of incident light may be collectively referred to as a pixel signal.

The correlated double sampler (CDS) circuit may remove undesired offset values of pixels known as the fixed pattern noise by sampling a pixel signal twice to remove the difference between these two samples. In some implementations, the correlated double sampler (CDS) circuit may compare pixel output voltages obtained before and after photocharges generated by incident light received in the unit pixels are accumulated in the sensing node so that only pixel output voltages based on the incident light can be measured.

The CDS circuit may sequentially sample and hold voltage levels of the reference signal and the image signal, which are provided to each of a plurality of column lines included in the pixel array.

In addition, the readout circuit 44 may include an analog-to-digital converter (ADC) for converting output signals of the CDS circuit into digital signals. In addition, the readout circuit 44 may include a buffer circuit that temporarily stores pixel data generated from the analog-to-digital converter (ADC) and outputs the pixel data under control of the timing controller 43. Since the pixel array 30 includes CAPD pixels, two column lines for transmitting the pixel signal may be assigned to each column of the pixel array 30, and structures for processing the pixel signal generated from each column line may be configured to correspond to the respective column lines.

The light source 10 may emit light (i.e., modulated light) modulated by a predetermined frequency to a scene captured by the image sensing device ISD. The image sensing device ISD may sense modulated light (i.e., incident light) reflected from the target objects 1 included in the scene, and may thus generate depth information for each unit pixel (PX).

A time delay based on the distance between the image sensing device ISD and each target object 1 may occur between the modulated light and the incident light. The time delay may be denoted by a phase difference between the signal generated by the image sensing device ISD and the modulated light signal MLS controlling the light source 10. An image processor (not shown) may calculate a phase difference generated in the output signal of the image sensing device ISD, and may thus generate a depth image including depth information for each unit pixel (PX).

In addition, the image sensing device (ISD) may generate color information for each color pixel by sensing visible light incident from the scene, and the image processor (not shown) may generate a color image including color information of the scene appearing in a signal being output from the image sensing device (ISD).

FIG. 2 is a schematic diagram illustrating an example of the pixel array 30 shown in FIG. 1 based on some implementations of the disclosed technology.

FIG. 2 illustrates a pixel array (PA) corresponding to a portion of the pixel array 30, and a pixel group 80 may have a structure in which pixel groups 80 with different unit pixels are repeatedly arranged in a row direction or a column direction.

Referring to FIG. 2, the pixel group 80 may include four adjacent pixels arranged in a (2×2) matrix having two rows and two columns. The unit pixels in each pixel group 80 include two types of pixels for performing different sensing operations: a first type of pixels that detect light from a target object or scene to capture the image of the target object or scene and one or more a second type of designated pixels to detect modulated light that is generated by the light source 10 and is reflected from the target object or scene for depth sensing. First, in this example, the first type of pixels include 3 color sensing pixels of a red pixel (PX_R) for detecting light corresponding to red among visible light and a green pixel (PX_G) for detecting light corresponding to green among visible light, and a blue pixel (PX_B) for detecting light corresponding to blue among visible light. The red and green pixels (PX_R) and (PX_G) may be disposed in a first row of the pixel group 80. The blue pixel (PX_B) and an infrared pixel (PX_IR) as a second type designated pixel for detecting light corresponding to infrared light for distance sensing may be disposed in a second row of the pixel group 80. The above-described arrangement is merely an example and other arrangements are possible while changing position of the pixels within the pixel group 80. Thus, the pixel group can be configured in various manners as long as three color pixels (PX_R, PX_G, PX_B) and one infrared pixel (PX_IR) are disposed within the pixel group 80.

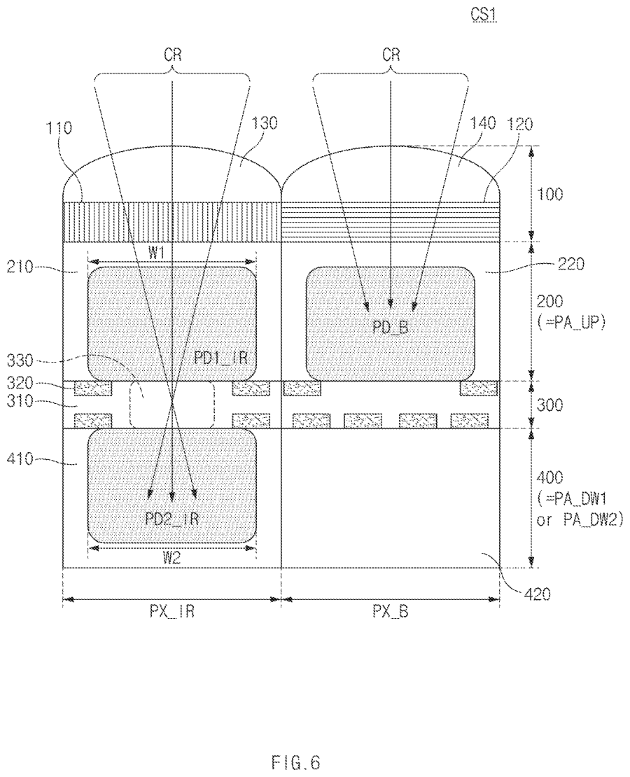

Notably, as further explained in the examples in FIGS. 6-13, the color pixels (PX_R, PX_G, PX_B) in the pixel group 80 include color filters that only allow visible light of selective colors to pass through to reach the respective photoelectric conversion elements of the color pixels while blocking the infrared light from the light source 10 to be detected by the color pixels. Conversely, the infrared pixel (PX_IR) includes a filter that only allows infrared light to pass through to reach its photoelectric conversion element while blocking the visible light. As such, the color pixels (PX_R, PX_G, PX_B) in the pixel group 80 are designated imaging sensing pixels and the infrared pixel (PX_IR) is the designated distance sensing pixel within the pixel group 80. Different pixel groups 80 are spatially distributed with in the pixel array 30 to capture not only the images in the incident light to the pixel array 30 but also the different distances detected at the different pixel groups 80.

The color pixels (PX_R, PX_G, PX_B) belonging to the pixel group 80 may be implemented as shared pixels. Specifically, each of the color pixels (PX_R, PX_G, PX_B) may independently include a photoelectric conversion element for detecting incident light and generating/accumulating photocharges corresponding to the intensity of incident light, and a transfer transistor for transferring photocharges to a floating diffusion (FD) node common to and shared by the color pixels. In some implementations, the color pixels (PX_R, PX_G, PX_B) may share a plurality of transistors for generating electrical signals corresponding to photocharges accumulated in their respective photoelectric conversion elements of different color pixels. The transfer transistor may transfer photocharges accumulated in each photoelectric conversion element of a particular color pixel to the floating diffusion (FD) node in response to a transfer signal received from the control circuit 41. The transfer signal supplied to each of the color pixels (PX_R, PX_G, PX_B) may be activated at different time points to prevent undesired color mixing or crosstalk between different color pixels (PX_R, PX_G, PX_B), so that the transfer transistors of the color pixels (PX_R, PX_G, PX_B) may not be turned on at the same time.

Elements shared by the color pixels (PX_R, PX_G, PX_B) may include a floating diffusion (FD) node for storing photocharges therein, and a plurality of transistors for reading out and resetting the FD. Here, the plurality of transistors may include a reset transistor for resetting the floating diffusion (FD) node to a power-supply voltage in response to a pixel reset signal, a drive transistor (or a source follower transistor) for generating an electrical signal corresponding to a voltage of the floating diffusion (FD) node, and a selection transistor for outputting the electrical signal received from the drive transistor to a column line in response to a row selection signal. Although the above-described embodiment has disclosed only a 4TR (i.e., four-transistor) structure as shown in FIG. 2 for convenience of description, other implementations are also possible, and it should be noted that the number of shared transistors to be used for the color pixels (PX_R, PX_G, PX_B) implemented as another structure (e.g., 3TR (three-transistor) structure or a 5TR (five-transistor) structure) may be increased or decreased as necessary or desired for a specific sensing application.

Devices or elements shared by the color pixels (PX_R, PX_G, PX_B) may be collectively referred to as a pixel output circuit of the color pixels (PX_R, PX_G, PX_B).

The infrared pixels (PX_IR) belonging to the pixel group 80 may have a 2-tap structure or a 4-tap structure. Here, the tap may refer to a unit for capturing reflected light in response to a demodulation control signal having a constant phase difference with the modulated light signal (MLS). In some implementations, the tap may refer to a capturing structure configured to capture reflected light in response to the demodulation control signal.

The 2-tap structure may include a first tap configured to generate an electrical signal obtained by capturing reflected light in response to a demodulation control signal having a phase difference of 0 degrees (0°) with respect to the modulated light signal (MLS), and a second tap configured to generate an electrical signal obtained by capturing reflected light in response to a demodulation control signal having a phase difference of 180 degrees (180°) with respect to the modulated light signal (MLS).

The 4-tap structure may include a first tap configured to generate an electrical signal obtained by capturing reflected light in response to a demodulation control signal having a phase difference of 0 degrees (0°) with respect to the modulated light signal (MLS), a second tap configured to generate an electrical signal obtained by capturing reflected light in response to a demodulation control signal having a phase difference of 180 degrees (180°) with respect to the modulated light signal (MLS), a third tap configured to generate an electrical signal obtained by capturing reflected light in response to a demodulation control signal having a phase difference of 90 degrees (90°) with respect to the modulated light signal (MLS), a fourth tap configured to generate an electrical signal obtained by capturing reflected light in response to a demodulation control signal having a phase difference of 270 degrees (270°) with respect to the modulated light signal (MLS).

The infrared pixel (PX_IR) may include a photoelectric conversion element configured to generate and accumulate photocharges corresponding to the intensity of reflected light, and a tap output circuit configured to generate an electrical signal corresponding to photocharges by connecting to the photoelectric conversion element. The tap output circuit may include a transfer transistor configured to transfer photocharges of the photoelectric conversion element to a floating diffusion (FD) node in response to a demodulation control signal, a floating diffusion node configured to accumulate photocharges, a reset transistor configured to reset the floating diffusion (FD) node to a power-supply voltage in response to a pixel reset signal, a drive transistor (or a source follower transistor) configured to generate an electrical signal corresponding to a voltage of the floating diffusion (FD) node, and a selection transistor configured to output the electrical signal received from the drive transistor to a column line in response to a row selection signal.

The tap output circuit may be independently provided to correspond to each tap. For example, when the infrared pixel (PX_IR) is implemented as a 2-tap structure, a first tap output circuit may be provided in the first tap and a second tap output circuit may be provided in the second tap. When the infrared pixel (PX_IR) is implemented as a 4-tap structure, a first tap output circuit may be provided in the first tap, a second tap output circuit may be provided in the second tap, a third tap output circuit may be provided in the third tap, and a fourth tap output circuit may be provided in the fourth tap.

Tap output circuits included in the infrared pixel (PX_IR) may be collectively referred to as a pixel output circuit of the infrared pixel (PX_IR).

The pixel array (PA) may be implemented using a first substrate (or an upper substrate) and a second substrate (or a lower substrate) that are stacked, and elements constituting the pixel group 80 can be distributed and arranged in the first substrate and the second substrate.

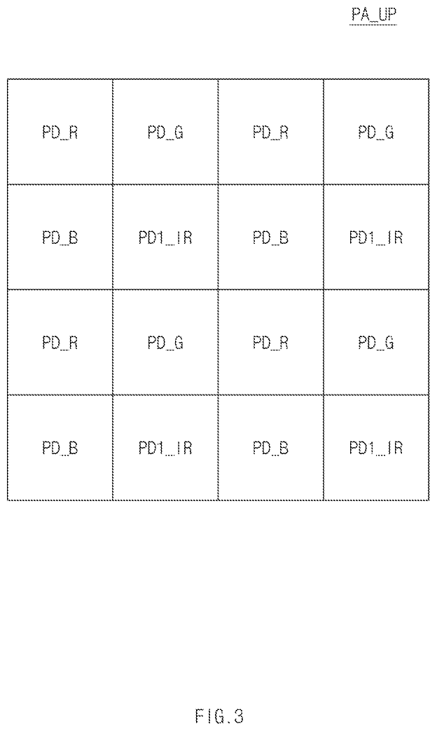

FIG. 3 is a schematic diagram briefly illustrating an example of an arrangement of elements on a first substrate (PA_UP) constituting the pixel array (PA) shown in FIG. 2 based on some implementations of the disclosed technology.

Referring to FIG. 3, the first substrate (PA_UP) may include photoelectric conversion elements (PD_R, PD_G, PD_B) of the color pixels (PX_R, PX_G, PX_B). In more detail, the photoelectric conversion element (PD_R) may be disposed at the position of the color pixel (PX_R), the photoelectric conversion element (PD_G) may be disposed at the position of the color pixel (PX_G), and the photoelectric conversion element (PD_B) may be disposed at the position of the color pixel (PX_B). In addition, the first substrate (PA_UP) may include a photoelectric conversion element (PD1_IR) of the infrared pixel (PX_IR) disposed at the position of the infrared pixel (PX_IR).

In some implementations, the first substrate (PA_UP) may include a photoelectric conversion element of each pixel disposed to correspond to the position of each pixel.

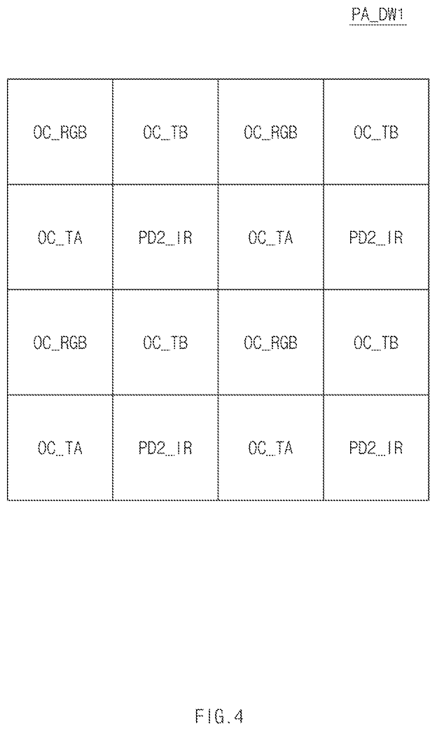

FIG. 4 is a schematic diagram briefly illustrating one example of an arrangement of elements on a second substrate constituting the pixel array shown in FIG. 2 based on some implementations of the disclosed technology.

FIG. 4 shows the arrangement shape of elements on the second substrate (PA_DW1) when the infrared pixel (PX_IR) has a 2-tap structure.

The second substrate (PA_DW1) may include a pixel output circuit (OC_RGB) of the color pixels (PX_R, PX_G, PX_B) disposed at the position corresponding to the red pixel (PX_R).

The second substrate (PA_DW1) may include a first tap output circuit (OC_TA) of the infrared pixel (PX_IR) disposed at the position corresponding to the blue pixel (PX_B).

The second substrate (PA_DW1) may include a second tap output circuit (OC_TB) of the infrared pixel (PX_IR) disposed at the position corresponding to the green pixel (PX_G).

The second substrate (PA_DW1) may include a photoelectric conversion element (PD2_IR) of the infrared pixel (PX_IR) disposed at the position of the infrared pixel (PX_IR).

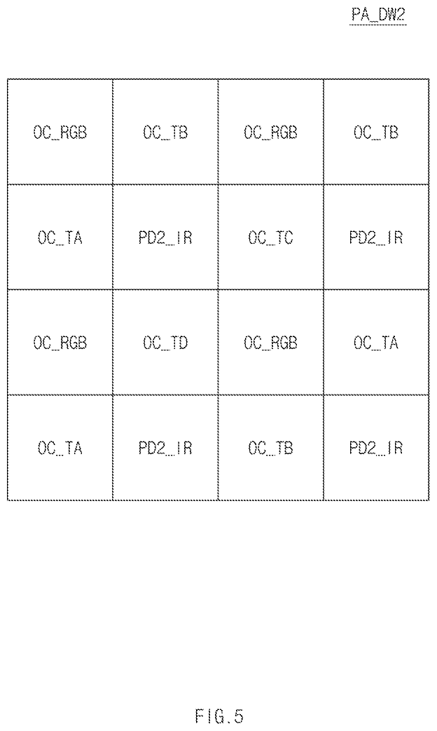

FIG. 5 is a schematic diagram briefly illustrating another example of an arrangement of elements on a second substrate constituting the pixel array shown in FIG. 2 based on some implementations of the disclosed technology.

FIG. 5 shows the arrangement of elements on the second substrate (PA_DW2) when the infrared pixel (PX_IR) has a 4-tap structure.

The second substrate (PA_DW2) may include a pixel output circuit (OC_RGB) of the color pixels (PX_R, PX_G, PX_B) disposed at the position corresponding to the red pixel (PX_R).

The second substrate (PA_DW2) may include a first tap output circuit (OC_TA) or a third tap output circuit (OC_TC) of the infrared pixel (PX_IR) disposed at the position corresponding to the blue pixel (PX_B).

The second substrate (PA_DW2) may include a second tap output circuit (OC_TB) or a fourth tap output circuit (OC_TD) of the infrared pixel (PX_IR) disposed at the position corresponding to the green pixel (PX_G).

The second substrate (PA_DW2) may include a photoelectric conversion element (PD2_IR) of the infrared pixel (PX_IR) disposed at the position of the infrared pixel (PX_IR).

The first to fourth tap output circuits disposed at positions corresponding to the blue pixel (PX_B) or the green pixel (PX_G) may be arranged adjacent to the photoelectric conversion element (PD2_IR) of the infrared pixel (PX_IR). As a result, each of the first to fourth tap output circuits (OC_TA˜OC_TD) can process photocharges accumulated in the photoelectric conversion element (PD2_IR) of the infrared pixel (PX_IR), and can thus convert the processed photocharges into an electrical signal.

According to the second substrate (PA_DW1) or the arrangement structure of elements on the second substrate (PA_DW1), the color pixels (PX_R, PX_G, PX_B) are implemented as a shared pixel structure in a manner that a pixel output circuit (OC_RGB) is disposed in a region of any one of the color pixels (PX_R, PX_G, PX_B), so that only the photoelectric conversion elements of the color pixels (PX_R, PX_G, PX_B) can be disposed in the first substrate (PA_UP), thereby increasing the volume of the photoelectric conversion elements of the color pixels (PX_R, PX_G, PX_B) and increasing the quantum efficiency (QE) of the photoelectric conversion elements of the color pixels (PX_R, PX_G, PX_B), resulting in reduction of the influence of noise.

The photoelectric conversion element (PD2_IR) of the infrared pixel (PX_IR) may be disposed in each of the first substrate and the second substrate, such that the volume and quantum efficiency (QE) of the photoelectric conversion element (PD2_IR) of the infrared pixel (PX_IR) can be increased as much as possible.

In addition, the tap output circuits for processing the photocharges accumulated in the photoelectric conversion element (PD2_IR) of the infrared pixel (PX_IR) may be distributed and disposed in the remaining regions of the color pixels (PX_R, PX_G, PX_B), so that the infrared pixel (PX_IR) can operate normally.

FIG. 6 is a cross-sectional view illustrating an example of the pixel array taken along the line A-A′ shown in FIG. 2 based on some implementations of the disclosed technology.

Referring to FIG. 6, a cross-section CS1 showing the pixel array taken along the line A-A′ with the shown in FIG. 2 is illustrated.

The cross-section CS1 may include a light incident layer 100, a first substrate 200, an intermediate layer 300, and a second substrate 400.

The light incident layer 100 may include optical filters 110 and 120 and microlenses 130 and 140.

The optical filters 110 and 120 may be formed over the first substrate 200, and may selectively transmit light (e.g., red light, green light, blue light, near infrared light, infrared light, etc.) of a specific wavelength band of incident light. The optical filter 110 included in the infrared pixel (PX_IR) may be used as a filter for selectively transmitting infrared light or near-infrared light, and the optical filter 120 included in the blue pixel (PX_B) may be used as a filter for selectively transmitting blue light. A grid structure (not shown) may be provided for absorbing or reflecting light. The grid structure may be disposed at a boundary between adjacent pixels in order to prevent light incident upon the optical filters 110 and 120 from being transferred to other pixels, but the scope of the disclosed technology is not limited thereto. For example, a location of the grid structure may be modified in various implementations without being limited to the boundary between adjacent pixels.

The microlenses 130 and 140 may be formed over the optical filters 110 and 120, respectively, and each of the microlenses 130 and 140 may be formed in a convex hemispherical shape, so that the microlenses 130 and 140 can increase light reception (Rx) efficiency by increasing light gathering power of incident light. An over-coating layer (not shown) may be additionally formed above or below the microlenses 130 and 140, so that the over-coating layer can suppress flare characteristics by preventing irregular or diffuse reflection of incident light received from the outside.

The first substrate 200 may include a top surface and a bottom surface facing away from the top surface. For example, the first substrate 200 may be or include a P-type or N-type bulk substrate, may be or include a substrate formed by growing a P-type or N-type epitaxial layer on the P-type bulk substrate, or may be or include a substrate formed by growing a P-type or N-type epitaxial layer on the N-type bulk substrate.

The first substrate 200 may include semiconductor regions 210 and 220, a first infrared photoelectric conversion element (PD1_IR), and a blue photoelectric conversion element (PD_B).

Each of the semiconductor regions 210 and 220 may be or include an epitaxial layer doped with P-type or N-type impurities, and other implementations are also possible. In some implementations, the semiconductor regions 210 and 220 may be provided to cover the first infrared photoelectric conversion element (PD1_IR) and a blue photoelectric conversion element (PD_B).

The first infrared photoelectric conversion element (PD1_IR) may be disposed in a region corresponding to the infrared pixel (PX_IR) in the semiconductor region 210 of the first substrate 200. The first infrared photoelectric conversion element (PD_IR) may generate and accumulate photocharges corresponding to the intensity of infrared light that has passed through the optical filter 110. The first infrared photoelectric conversion element (PD_IR) may be arranged to occupy as large a region as possible to increase a fill factor indicating light reception (Rx) efficiency. For example, the first infrared photoelectric conversion element (PD1_IR) may be implemented as a photodiode, a phototransistor, a photogate, a pinned photoelectric conversion element, or a combination thereof.

When the first infrared photoelectric conversion element (PD1_IR) is implemented as a photodiode, the first infrared photoelectric conversion element (PD1_IR) can be formed as an N-type doped region through an ion implantation process for N-type ion implantation. In some implementations, the photodiode may be formed in a shape in which a plurality of doped regions is stacked. In this case, the lower doped region may be formed through implantation of P-type ions and N⁺-type ions, and the upper doped region may be formed through implantation of N⁻-type ions.

The blue photoelectric conversion element (PD_B) may be disposed in a region corresponding to the blue pixel (PX_B) in the semiconductor region 220 of the first substrate 200. The blue photoelectric conversion element (PD_B) may generate and accumulate photocharges corresponding to the intensity of blue light that has passed through the optical filter 120. The blue photoelectric conversion element (PD_B) may be arranged to occupy as large a region as possible to increase a fill factor indicating light reception (Rx) efficiency. Materials included in the blue photoelectric conversion element (PD_B) and a method for forming the blue photoelectric conversion element (PD_B) are substantially the same as those of the first infrared photoelectric conversion element (PD1_IR), and as such redundant description thereof will herein be omitted for brevity.

Although FIG. 6 shows only the blue photoelectric conversion element (PD_B) as an example, the red photoelectric conversion element (PD_R) may be included in the red pixel (PX_R), and the green photoelectric conversion element (PD_G) may be included in the green pixel (PX_G). The red photoelectric conversion element (PD_R), the green photoelectric conversion element (PD_G), and the blue photoelectric conversion element (PD_B) may be collectively referred to as color photoelectric conversion elements.

The intermediate layer 300 may be disposed between the first substrate 200 and the second substrate 400. The intermediate layer 300 may include an interlayer insulation layer 310, an interconnect region 320, and a light transmission region 330. In some implementations, the intermediate layer 300 may not include all of the interlayer insulation layer 310, the interconnect region 320, and the light transmission region 330, and at least one of the interlayer insulation layer 310, the interconnect region 320, or the light transmission region 330 can be omitted.

Although not shown in FIG. 6, a source and a drain constituting each of the plurality of transistors configured to convert photocharges accumulated in the photoelectric conversion element (PD_IR or PD_B) of each pixel (PX_IR or PX_B) into a pixel signal may be formed in an inner region of the first substrate 200 or the second substrate 400. Here, the inner region of the first substrate 200 or the second substrate 400 may be adjacent to the bottom surface of the first substrate 200 or the top surface of the second substrate 400. In some implementations, each of the source and drain may be or include an impurity region doped with P-type or N-type impurities.

Pixel gates (not shown) that constitute a transistor together with a source and a drain included in the first substrate 200 or the second substrate 400 may be formed in an inner region of the intermediate layer 300 adjacent to the bottom surface of the first substrate 200 or the top surface of the second substrate 400. Each of the pixel gates (not shown) may include a gate insulation layer for electrical isolation from the first substrate 200 or the second substrate 400, and a gate electrode for receiving a corresponding control signal.

The interlayer insulation layer 310 may electrically isolate the interconnect regions 320 from each other, and may physically support the interconnect regions 320.

The interconnect region 320 may include a plurality of interconnect layers for driving the pixel array (PA), and pixel gates and metal interconnects may be disposed in the plurality of interconnect layers.

The light transmission region 330 may refer to a layer for transferring infrared light that has passed through the first substrate 200 to the second substrate 400. Specifically, the light transmission region 330 may be disposed in a region through which a chief ray (CR) passes. The light transmission region 330 may not include an interconnect layer that may interfere with transmission of infrared light. Thus, the light transmission region 330 may refer to a region in which no interconnect layer is disposed so that infrared light can pass therethrough, and may be defined by the position and shape of the interconnect layer. The light transmission regions 330 shown in FIGS. 6 to 13 are schematically illustrated to facilitate understanding of the present embodiment, and the light transmission regions 330 are not limited to the locations as shown in FIGS. 6-13. Rather, each of the light transmission regions 330 may refer to a region in which no interconnect layer is disposed so that infrared light can be transferred thereto without any loss.

In addition, the light transmission region 330 may not be disposed in the blue pixel (PX_B) serving as a color pixel, but may be disposed only in the infrared pixel (PX_IR). The light transmission region 330 may overlap with the center of the infrared pixel (PX_IR), but the scope of the disclosed technology is not limited thereto. Thus, in some implementations, the light transmission region 330 may be disposed not to overlap with the center of the infrared pixel (PX_IR).

The second substrate 400 may include a top surface and a bottom surface facing away from each other. For example, the second substrate 400 may be a P-type or N-type bulk substrate, may be a substrate formed by growing a P-type or N-type epitaxial layer on the P-type bulk substrate, or may be a substrate formed by growing a P-type or N-type epitaxial layer on the N-type bulk substrate. The second substrate 400 may include semiconductor regions (410, 420) and a second infrared photoelectric conversion element (PD2_IR).

Each of the semiconductor regions (410, 420) may be an epitaxial layer doped with P-type or N-type impurities, and other implementations are also possible.

The second infrared photoelectric conversion element (PD2_IR) in the second substrate 400 may be disposed in a region corresponding to the infrared pixel (PX_IR) in the semiconductor region 410 of the second substrate 400. In the illustrated example, the two substrates 200 and 400 are aligned so that the semiconductor region 410 in the second substrate 400 is aligned with and is located below the semiconductor region 210 of the first substrate 200 and the semiconductor region 420 is aligned with and is located below the semiconductor region 220 of the first substrate 200. Under this design, the second infrared photoelectric conversion element (PD2_IR) may generate and accumulate photocharges corresponding to the intensity of infrared light that has passed through the first substrate 200. The second infrared photoelectric conversion element (PD2_IR) may be arranged to occupy as large a region as possible to increase a fill factor indicating light reception (Rx) efficiency. Materials constituting the second infrared photoelectric conversion element (PD2_IR) and a method for forming the second infrared photoelectric conversion element (PD2_IR) are substantially the same as those of the first infrared photoelectric conversion element (PD1_IR), and as such redundant description thereof will herein be omitted for brevity.

In some implementations, a photoelectric conversion element may not be disposed in the semiconductor region 420 of the blue pixel (PX_B), and a transistor for processing photocharges accumulated in the photoelectric conversion element may be disposed in the semiconductor region 420 as shown in FIG. 4 or FIG. 5.

The first infrared photoelectric conversion element (PD1_IR) and the second infrared photoelectric conversion element (PD2_IR) may be stacked in a vertical direction (or a first direction) and may overlap each other in a vertical direction (or a first direction).

Since infrared light has a longer wavelength than visible light, the infrared light has a longer penetration depth than the visible light. Accordingly, most of visible light of the chief ray (CR) that has passed through the optical filter 120 may be absorbed by the blue photoelectric conversion element (PD_B), but infrared light of the chief ray (CR) that has passed through the optical filter 110 may be partially absorbed (or photoelectrically converted) by the first infrared photoelectric conversion element (PD1_IR) and may then be transmitted to the intermediate layer 300. The light transmission region 330 of the intermediate layer 300 may transfer the infrared light that has passed through the first infrared photoelectric conversion element (PD1_IR) to the second infrared photoelectric conversion element (PD2_IR) of the second substrate 400. The second infrared photoelectric conversion element (PD2_IR) may absorb (or photoelectrically convert) most of the infrared light, and may generate photocharges corresponding to the intensity of the infrared light.

According to the embodiment of the disclosed technology, the two substrates (200, 400) may be stacked and the photoelectric conversion elements (PD1_IR, PD2_IR) for detecting infrared light may be respectively disposed in the two substrates (200, 400) in a manner that the light transmission region 330 is formed between the two photoelectric conversion elements (PD1_IR, PD2_IR), thereby increasing photoelectric conversion efficiency for infrared light having a long penetration depth.

In addition, the height and curvature of the microlens 130 can be experimentally optimized such that a focal point of the chief ray (CR) is located at the light transmission region 330 so as to maximize photoelectric conversion efficiency by the first infrared photoelectric conversion element (PD1_IR) and the second infrared photoelectric conversion element (PD2_IR).

The first infrared photoelectric conversion element (PD1_IR) and the second infrared photoelectric conversion element (PD2_IR) may be directly electrically connected to each other through the intermediate layer 300 (e.g., using a through silicon via (TSV)), or may be indirectly connected to the same floating diffusion (FD) node through transfer transistors respectively connected to the first infrared photoelectric conversion element (PD1_IR) and the second infrared photoelectric conversion element (PD2_IR).

As can be seen from FIG. 6, the first infrared photoelectric conversion element (PD1_IR) may have a first width W1, and the second infrared photoelectric conversion element (PD2_IR) may have a second width W2. In some implementations, the first width W1 and the second width W2 may be equal to each other.

Although FIG. 6 is a cross-sectional view showing the infrared pixel (PX_IR) and the blue pixel (PX_B) taken along the line A-A′ for convenience of description, other implementations are also possible, and the structure of FIG. 6 can be substantially applied to the cross-sections of the infrared pixel (PX_IR) and the red pixel (PX_R) taken along the other line or the cross-sections of the infrared pixel (PX_IR) and the green pixel (PX_G) taken along the other line.

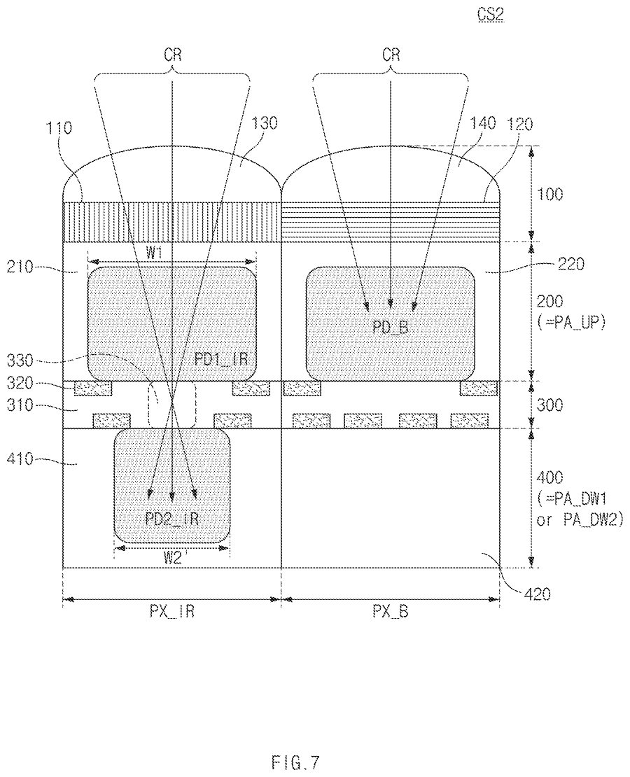

FIG. 7 is a cross-sectional view illustrating another example of the pixel array taken along the line A-A′ shown in FIG. 2 based on some implementations of the disclosed technology.

Referring to FIG. 7, a cross-section CS2 showing the pixel array (PA) taken along the line A-A′ shown in FIG. 2 is illustrated.

The remaining parts of the cross-section CS2 shown in FIG. 7 other than some characteristics different from those of the cross-section CS1 shown in FIG. 6 may be substantially identical in structure to the cross-section CS1 shown in FIG. 6, and as such redundant description thereof will herein be omitted for brevity.

As can be seen from the cross-section CS2, the first infrared photoelectric conversion element (PD1_IR) may have a first width W1 and the second infrared photoelectric conversion element (PD2_IR) may have a second width W2. In some implementations, the first width W1 may be greater than the second width W2, such that the width of the light transmission region 330 can also be reduced.

The second infrared photoelectric conversion element (PD2_IR) may be formed to be smaller than the first infrared photoelectric conversion element (PD1_IR), so that a space in which the pixel output circuit can be disposed in the second substrate 400 can be secured. As the size of some transistors (e.g., a drive transistor) included in the pixel output circuit increases, the amount of noise included in the pixel signal can be reduced.

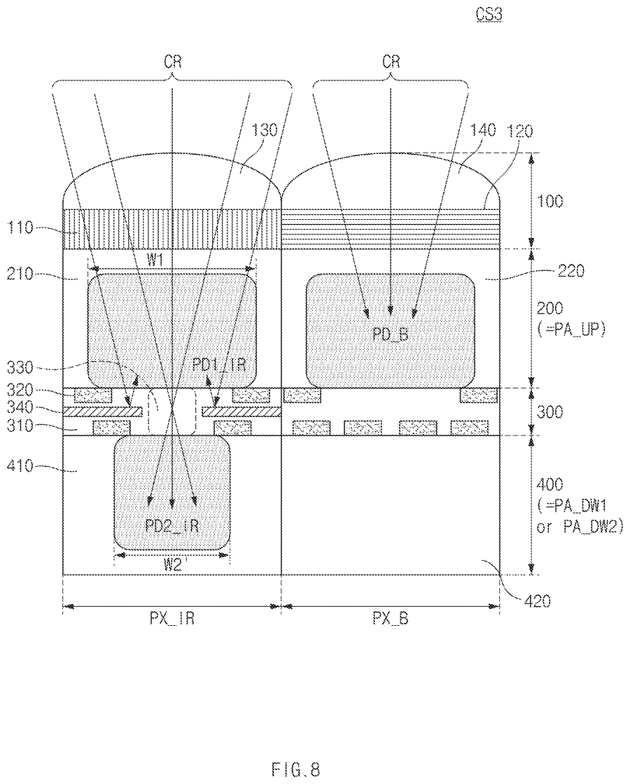

FIG. 8 is a cross-sectional view illustrating another example of the pixel array taken along the line A-A′ shown in FIG. 2 based on some implementations of the disclosed technology.

Referring to FIG. 8, a cross-section CS3 showing the pixel array (PA) taken along the line A-A′ shown in FIG. 2 is illustrated. The remaining parts of the cross-section CS3 shown in FIG. 8 other than some characteristics different from those of the cross-section CS2 shown in FIG. 7 may be substantially identical in structure to the cross-section CS2 shown in FIG. 7, and as such redundant description thereof will herein be omitted for brevity.

The intermediate layer 300 may further include a light reflection layer 340 disposed in a region other than the light transmission area 330 in the infrared pixel (PX_IR). In other words, the light transmission region 330 may be defined by the light reflection layer 340 together with the interconnect layer. The light reflection layer 340 may reflect infrared light, which is transferred to the intermediate layer 300 by penetrating the first substrate 200, toward the first infrared photoelectric conversion element (PD1_IR), thereby increasing light reception efficiency of the first infrared photoelectric conversion element (PD_IR).

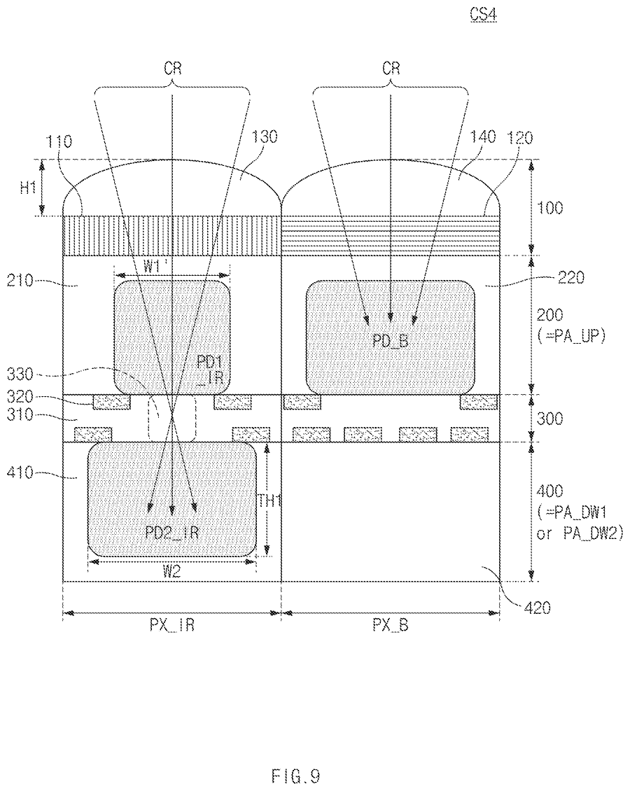

FIG. 9 is a cross-sectional view illustrating another example of the pixel array taken along the line A-A′ shown in FIG. 2 based on some implementations of the disclosed technology.

Referring to FIG. 9, a cross-section CS4 showing the pixel array (PA) taken along the line A-A′ shown in FIG. 2 is illustrated.

The remaining parts of the cross-section CS4 shown in FIG. 9 other than some characteristics different from those of the cross-section CS1 shown in FIG. 6 may be substantially identical in structure to the cross-section CS1 shown in FIG. 6, and as such redundant description thereof will herein be omitted for brevity.

As can be seen from the cross-section CS4, the first infrared photoelectric conversion element (PD1_IR) may have a first width W1, and the second infrared photoelectric conversion element (PD2_IR) may have a second width W2. In some implementations, the first width W1 may be smaller than the second width W2. Accordingly, the width of the light transmission region 330 may also be reduced.

The first infrared photoelectric conversion element (PD1_IR) may be formed to be smaller than the second infrared photoelectric conversion element (PD2_IR), so that the distance between the first infrared photoelectric conversion element (PD1_IR) and the blue photoelectric conversion element (PD_B) in the first substrate 200 may increase, thereby reducing the possibility of electrical crosstalk.

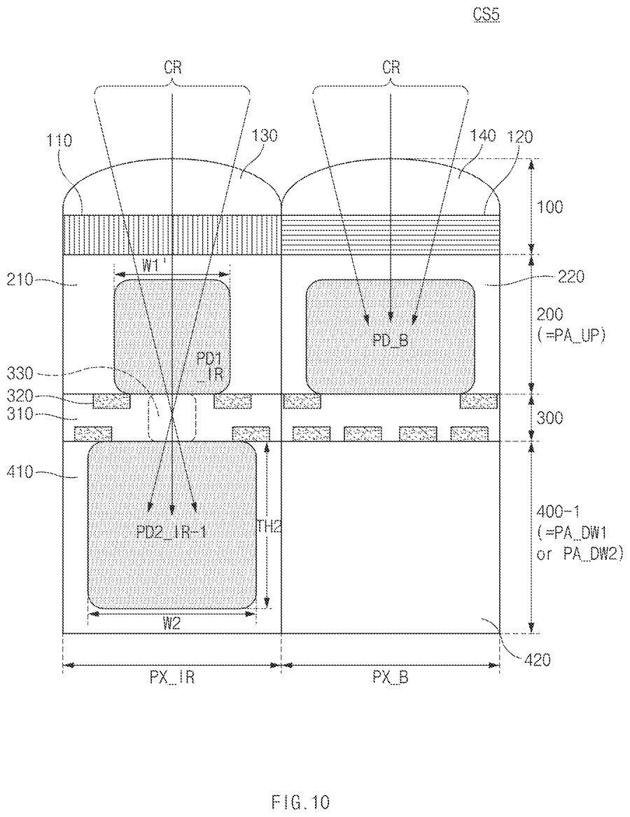

FIG. 10 is a cross-sectional view illustrating another example of the pixel array taken along the line A-A′ shown in FIG. 2 based on some implementations of the disclosed technology.

Referring to FIG. 10, a cross-section CS5 showing the pixel array (PA) taken along the line A-A′ shown in FIG. 2 is illustrated.

The remaining parts of the cross-section CS5 shown in FIG. 10 other than some characteristics different from those of the cross-section CS4 shown in FIG. 9 may be substantially identical in structure to the cross-section CS4 shown in FIG. 9, and as such redundant description thereof will herein be omitted for brevity.

As can be seen from the cross-section CS5, the second substrate 400-1 may have a greater thickness than the first substrate 200. Accordingly, a thickness TH2 of the second infrared photoelectric conversion element (PD2_IR-1) of the cross-section CS5 may be greater than a thickness TH1 of the second infrared photoelectric conversion element (PD2_IR) shown in the cross-section CS4. Accordingly, the second infrared photoelectric conversion element (PD2_IR-1) may have a relatively high photoelectric conversion efficiency for infrared light having a long penetration depth.

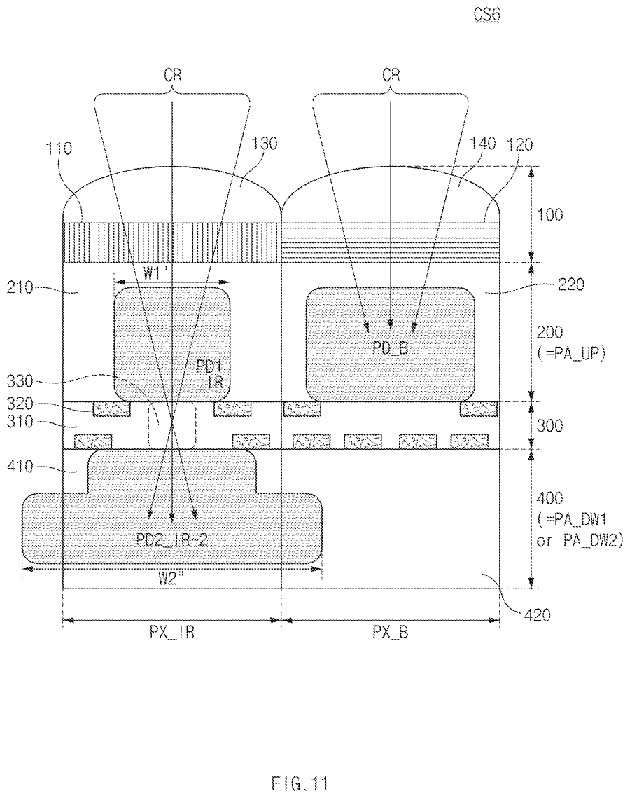

FIG. 11 is a cross-sectional view illustrating another example of the pixel array taken along the line A-A′ shown in FIG. 2 based on some implementations of the disclosed technology.

Referring to FIG. 11, a cross-section CS6 showing the pixel array (PA) taken along the line A-A′ shown in FIG. 2 is illustrated.

The remaining parts of the cross-section CS6 shown in FIG. 11 other than some characteristics different from those of the cross-section CS4 shown in FIG. 9 may be substantially identical in structure to the cross-section CS4 shown in FIG. 9, and as such redundant description thereof will herein be omitted for brevity.

As can be seen from the cross-section CS6, the second infrared photoelectric conversion element (PD2_IR-2) of the second substrate 400 may include an upper region having the same width as the second width W2 of the second infrared photoelectric conversion element (PD 2_IR) of the cross-section CS5, and a lower region having a second width W2 greater than the second width W2 of the second infrared photoelectric conversion element (PD 2_IR). Since the source or drain of the pixel output circuit is formed to be in contact with or adjacent to a top surface of the second substrate 400, the second infrared photoelectric conversion element (PD2_IR-2) may be formed to have a relatively narrow upper region and a relatively wide lower region so as to avoid interference with the source or drain. In some implementations, the lower region of the second infrared photoelectric conversion element (PD2_IR-2) may extend to a region corresponding to another adjacent pixel (e.g., PX_B). In this case, the lower region of the second infrared photoelectric conversion element (PD2_IR-2) may vertically overlap with at least a portion of the blue photoelectric conversion element (PD_B).

A dual structure of the second infrared photoelectric conversion element (PD2_IR-2) may be formed through two ion implantation processes, and other implementations are also possible.

The second infrared photoelectric conversion element (PD2_IR-2) may have a larger volume and a higher photocharge storage capacity than the second infrared photoelectric conversion element (PD2_IR) of the cross-section CS5, so that it is possible to measure the distance to the target object 1 without overflow even under high illuminance conditions, thereby improving high dynamic range (HDR) performance.

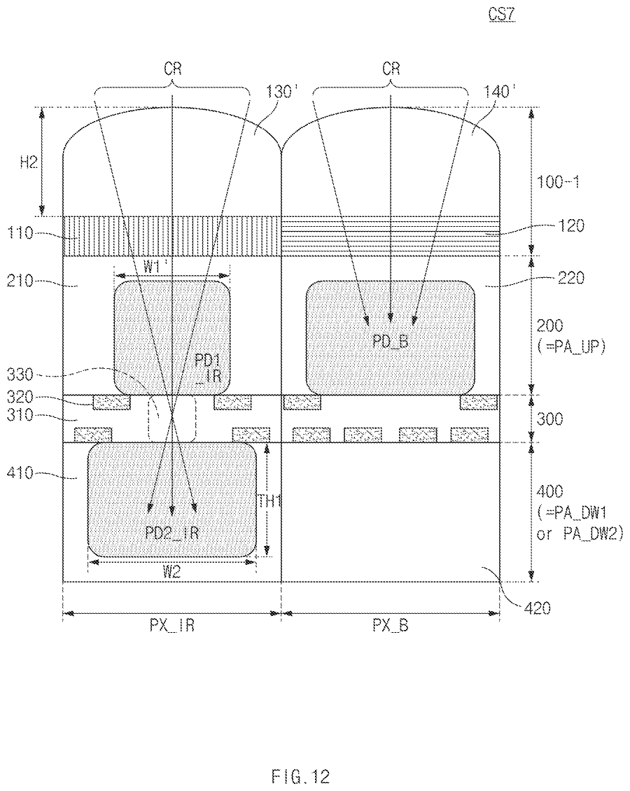

FIG. 12 is a cross-sectional view illustrating another example of the pixel array taken along the line A-A′ shown in FIG. 2 based on some implementations of the disclosed technology.

Referring to FIG. 12, a cross-section CS7 showing the pixel array (PA) taken along the line A-A′ shown in FIG. 2 is illustrated.

The remaining parts of the cross-section CS7 shown in FIG. 12 other than some characteristics different from those of the cross-section CS4 shown in FIG. 9 may be substantially identical in structure to the cross-section CS4 shown in FIG. 9, and as such redundant description thereof will herein be omitted for brevity.

Each of the microlenses 130 and 140 of a light incident layer 100-1 shown in the cross-section CS7 may have a second height higher than the first height H1 of the microlenses 130 and 140 shown in the cross-section CS4. As a result, the focal point of the chief ray (CR) having passed through the light incident layer 100-1 may be located higher than that of the cross-section CS4. In some implementations, each of the microlenses 130 and 140 may have a curvature and a height H2 such that the focal point of each of the microlenses 130 and 140 can be located at the first infrared photoelectric conversion element (PD1_IR).

The focal point of the chief ray (CR) moves upward, so that the chief ray (CR) can be transferred to the second infrared photoelectric conversion element (PD2_IR) in a manner that the chief ray (CR) can be spread out in a more diffused pattern, thereby increasing photoelectric conversion efficiency of the second infrared photoelectric conversion element (PD2_IR).

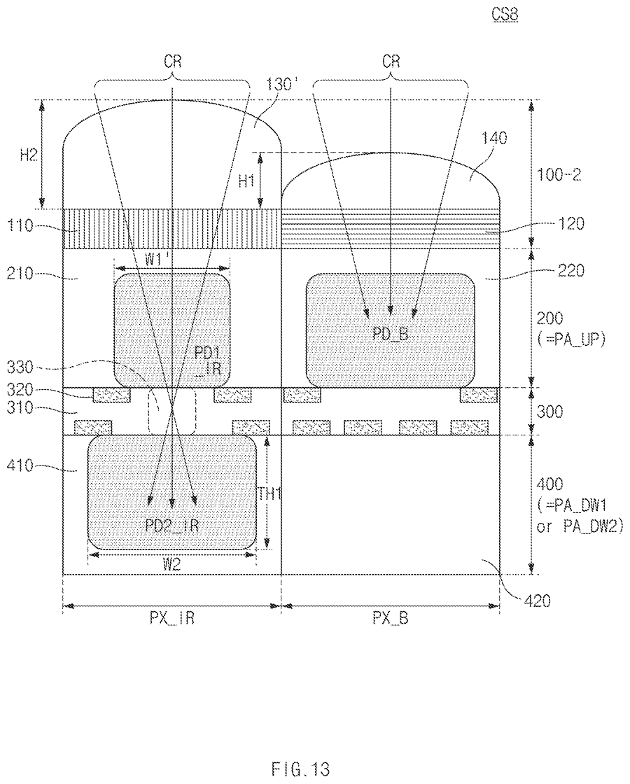

FIG. 13 is a cross-sectional view illustrating another example of the pixel array taken along the line A-A′ shown in FIG. 2 based on some implementations of the disclosed technology.

Referring to FIG. 13, a cross-section CS8 showing the pixel array (PA) taken along the line A-A′ shown in FIG. 2 is illustrated.

The remaining parts of the cross-section CS8 shown in FIG. 13 other than some characteristics different from those of the cross-section CS7 shown in FIG. 12 may be substantially identical in structure to the cross-section CS7 shown in FIG. 12, and as such redundant description thereof will herein be omitted for brevity.

As can be seen from the cross-section CS8, the microlens 130 of a light incident layer 100-2 may have a second height H2 in the same manner as in the cross-section CS7, but the microlens 140 may have a second height H2 in the same manner as in the cross-section CS4. As a result, the focal point of the chief ray (CR) having passed through a light incident layer 100-2 moves upward in the infrared pixel (PX_IR), so that the chief ray (CR) can be transferred to the second infrared photoelectric conversion element (PD2_IR) in a manner that the chief ray (CR) can be spread out in a more diffused pattern, thereby increasing photoelectric conversion efficiency of the second infrared photoelectric conversion element (PD2_IR). On the other hand, the focal point of the chief ray (CR) having passed through the light incident layer 100-2 may be located at the same level as the cross-section CS4 in the blue pixel (PX_B) so as to prevent the chief ray (CR) from being more spread out, so that the photoelectric conversion efficiency of the blue photoelectric conversion element (PD_B) can be prevented from being degraded.

As is apparent from the above description, the image sensing device based on some implementations of the disclosed technology can enable photoelectric conversion elements to be arranged at optimal positions in a structure in which color pixels and depth pixels are mixed and arranged, thereby improving pixel performance and maximizing area efficiency.

The embodiments of the disclosed technology may provide a variety of effects capable of being directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a first substrate configured to include a first infrared photoelectric conversion element structured to respond to infrared light to generate photocharges corresponding to an intensity of infrared light received by the first infrared photoelectric conversion element, and a color photoelectric conversion element structured to respond to visible light to generate photocharges corresponding to an intensity of visible light received by the color photoelectric conversion element; and
a second substrate stacked on the first substrate and configured to include a second infrared photoelectric conversion element structured to respond to infrared light to generate photocharges corresponding to an intensity of infrared light that passes through the first infrared photoelectric conversion element and is received by the second infrared photoelectric conversion element.

2. The image sensing device according to claim 1, further comprising:
an intermediate layer disposed between the first substrate and the second substrate and configured to transfer the infrared light having passed through the first infrared photoelectric conversion element to the second infrared photoelectric conversion element.

3. The image sensing device according to claim 1, wherein:
a pixel output circuit for processing photocharges of the first and second infrared photoelectric conversion elements or photocharges of the color photoelectric conversion element is disposed in the second substrate overlapping the color photoelectric conversion element.

4. The image sensing device according to claim 1, wherein the color photoelectric conversion element includes:
a red photoelectric conversion element configured to generate photocharges corresponding to intensity of red light;
a green photoelectric conversion element configured to generate photocharges corresponding to intensity of green light; and
a blue photoelectric conversion element configured to generate photocharges corresponding to intensity of blue light,
wherein, in the first substrate, the red photoelectric conversion element, the green photoelectric conversion element, the blue photoelectric conversion element, and the first infrared photoelectric conversion element are disposed in a matrix including two rows and two columns.

5. The image sensing device according to claim 4, wherein:
in the second substrate, a pixel output circuit for processing photocharges accumulated in each of the red photoelectric conversion element, the green photoelectric conversion element, and the blue photoelectric conversion element is disposed below the red photoelectric conversion element; and
in the second substrate, a tap output circuit for processing photocharges accumulated in each of the first infrared photoelectric conversion element and the second infrared photoelectric conversion element is disposed below the green photoelectric conversion element or the blue photoelectric conversion element.

6. The image sensing device according to claim 1, wherein:
the first infrared photoelectric conversion element has a same width as a width of the second infrared photoelectric conversion element.

7. The image sensing device according to claim 1, wherein:
the first infrared photoelectric conversion element has a larger width than a width of the second infrared photoelectric conversion element.

8. The image sensing device according to claim 7, further comprising:
a light reflection layer disposed below the first infrared photoelectric conversion element, and configured to reflect the infrared light passing through the first infrared photoelectric conversion element toward the first infrared photoelectric conversion element.

9. The image sensing device according to claim 1, wherein:
the first infrared photoelectric conversion element has a smaller width than a width of the second infrared photoelectric conversion element.

10. The image sensing device according to claim 9, wherein:
the second substrate has a larger thickness than a thickness of the first substrate; and
the second infrared photoelectric conversion element has a larger thickness than a thickness of the first infrared photoelectric conversion element.

11. The image sensing device according to claim 9, wherein the second infrared photoelectric conversion element includes:
an upper region and a lower region disposed under the upper region,
wherein the upper region has a smaller width than a width of the lower region.

12. The image sensing device according to claim 11, wherein:
the lower region is configured to vertically overlap at least a portion of the color photoelectric conversion element.

13. The image sensing device according to claim 9, further comprising:
at least one microlens disposed over the first substrate and configured to condense the infrared light or the visible light,
wherein the at least one microlens disposed over the first infrared photoelectric conversion element has a higher height than a height of the at least one microlens disposed over the color photoelectric conversion element.

14. The image sensing device according to claim 9, further comprising:
at least one microlens disposed over the first substrate and configured to condense the infrared light or the visible light,
wherein a focal point of the at least one microlens is located at the first infrared photoelectric conversion element.

15. An image sensing device comprising:
a pixel array configured to include an infrared pixel for generating photocharges corresponding to intensity of infrared light and a color pixel for generating photocharges corresponding to intensity of visible light,
wherein
the infrared pixel includes photoelectric conversion elements disposed in each of a first substrate and a second substrate that are stacked on each other, and
the color pixel includes a photoelectric conversion element disposed in the first substrate.

16. The image sensing device according to claim 15, wherein the photoelectric conversion elements included in the infrared pixel include:
a first infrared photoelectric conversion element disposed over the first substrate; and
a second infrared photoelectric conversion element disposed over the second substrate,
wherein the photoelectric conversion element included in the color pixel is a color photoelectric conversion element configured to generate photocharges in response to a reception of the visible light.

17. The image sensing device according to claim 16, wherein:
a pixel output circuit for processing photocharges of the first and second infrared photoelectric conversion elements or photocharges of the color photoelectric conversion element is disposed in the second substrate overlapping the color photoelectric conversion element.

18. The image sensing device according to claim 16, wherein the color photoelectric conversion element includes:
a red photoelectric conversion element configured to generate photocharges corresponding to intensity of red light;
a green photoelectric conversion element configured to generate photocharges corresponding to intensity of green light; and
a blue photoelectric conversion element configured to generate photocharges corresponding to intensity of blue light,
wherein, in the first substrate, the red photoelectric conversion element, the green photoelectric conversion element, the blue photoelectric conversion element, and the first infrared photoelectric conversion element are disposed in a matrix including two rows and two columns.

19. The image sensing device according to claim 18, wherein:
in the second substrate, a pixel output circuit for processing photocharges accumulated in each of the red photoelectric conversion element, the green photoelectric conversion element, and the blue photoelectric conversion element is disposed below the red photoelectric conversion element; and
in the second substrate, a tap output circuit for processing photocharges accumulated in each of the first infrared photoelectric conversion element and the second infrared photoelectric conversion element is disposed below the green photoelectric conversion element or the blue photoelectric conversion element.
